(19) United States
(12) Patent Application Publication
(10) Pub. No.: US 2025/0167575 A1
(43) Pub. Date: May 22, 2025

(54) METHOD AND SYSTEM FOR CONDITIONING A BATTERY MODULE

(71) Applicant: AVL DiTest GmbH, Graz (AT)

(72) Inventor: Manuel Schober, Riegersburg (AT)

(21) Appl. No.: 18/842,550

(22) PCT Filed: Feb. 28, 2023
(86) PCT No.: PCT/AT2023/060054

§ 371 Date: Aug. 29, 2024

(30) Foreign Application Priority Data
Mar. 2, 2022 (AT) A50138/2022

(51) Int. Cl. H02J 7/00; G01R 31/367; H01M 10/44

(52) U.S. Cl. CPC H02J 7/0069; G01R 31/367; H01M 10/446; H02J 7/007182; H02J 7/007194

(57) ABSTRACT

The invention relates to a method for conditioning a battery module, in particular a battery module of a traction battery, to a predetermined target voltage. The invention also relates to an associated system. The battery module is charged or discharged with a charging current by a conditioning unit or a charging apparatus, until a voltage, which drops between a positive and a negative terminal of the battery module, reaches a first switch-off voltage. When the first switch-off voltage is reached, the charging current is switched off and a relaxation curve between the positive and negative terminals of the battery module is measured by the conditioning unit for a predetermined period-of-time. A model of the battery module is derived from this measured relaxation curve by an analysis unit, which model is used to determine the entire relaxation curve. A second switch-off voltage is then determined from the entire determined relaxation curve by the analysis unit in such way that, after the charging current has been switched off, when the second switch-off voltage has been reached, the predetermined target voltage is assumed as the open-circuit voltage of the battery module. The battery module then continues to be charged or discharged with the charging current, until the second switch-off voltage is reached by the voltage dropping between the positive and negative terminal of the battery module. The charging current is then switched off and the predetermined target voltage is set at the battery module as a result of the relaxation curve.

### TECHNICAL FIELD

The present invention relates to a method for conditioning a battery module, in particular a battery module of a traction battery, to a predetermined target voltage. Furthermore, the present invention relates to an associated system for carrying out the method for conditioning the battery module.

### PRIOR ART

Nowadays, as in many electrically powered systems (e.g., mobile phones, electronic devices, etc.), rechargeable batteries or so-called secondary batteries are also used in electrically powered vehicles. Electric vehicles or hybrid vehicles usually have a high-voltage battery in the drive train in addition to an electric drive unit or an electric motor to drive the vehicle, which acts as a drive battery or traction battery and provides electrical energy for the vehicle's electric drive unit. These batteries are usually rechargeable and usually consist of several battery modules connected together. Such battery modules consist, for example, of a few to a large number of accumulator cells or cell blocks connected in parallel and series. Traction batteries are differentiated depending on the materials used for the accumulator cells. For example, lead-acid battery systems, nickel-cadmium battery systems, lithium-ion battery systems, etc. can be used as traction batteries in electrically powered vehicles.

If a defective battery module is detected in a traction battery of a hybrid or electric vehicle, it is usually necessary to replace the defective battery module with a new battery module. Battery modules are usually stored in a state that is geared towards optimal, long-term storage—e.g., at a charge level of 30%, etc. Before being installed in an electrically powered vehicle, however, a new battery module must be adapted to the charge level—the so-called state of charge (SoC)—of the other battery modules in the traction battery so that the traction battery can be activated after the battery module has been replaced and so that the overall battery system in the car functions properly.

Before installation and startup in practical operation, the battery module is therefore subjected to a special charging process (i.e., a special charge or discharge), which is also referred to as “conditioning.” For this special process, which prepares the battery module for installation, a so-called conditioning unit or a module conditioning system can be used. The battery module to be installed is connected to the conditioning unit, for example via connecting cables, and is brought to a desired charge level, for example by appropriate charging or discharging, and is thus matched to the current charge level of the battery modules of the traction battery. The conditioning unit determines a target voltage which corresponds to the desired state of charge for the battery module. The target voltage is, for example, a voltage which results as a steady state open-circuit voltage of the battery module after the end of the conditioning process—i.e., after the charging or discharging process. The open-circuit voltage is a voltage that depends on the current state of charge and is present between a positive terminal and a negative terminal of the battery module without a connected load. The open-circuit voltage that occurs in the steady state is also called the open-circuit voltage of the battery module.

Different charging methods can be used to charge rechargeable battery modules. The charging methods differ in the manner in which they control the current and voltage when charging the battery module. Battery modules are usually charged using a constant current or a constant voltage. For battery modules, such as lithium-ion accumulator systems, a so-called IU charging method is used. The IU method combines the constant current charging method with the constant voltage charging method and is also referred to as the “constant current constant voltage” or CCCV method for short. In the CCCV method, charging is first carried out with a constant charging current until a predetermined voltage limit, e.g., an end-of-charge voltage, is reached between the terminals of the battery module—usually with a charging unit or conditioning unit connected. Afterwards, charging continues at a constant voltage, with the charging current automatically decreasing towards the end of the charging process. If the charging current reaches or falls below a defined current limit or a specified period-of-time has elapsed, charging of the battery module is terminated. Although the CCCV method ensures that a maximum permissible voltage and a charging current—usually recommended by the manufacturer—are not exceeded, this charging method only makes it possible to charge a battery module to a desired charge level and/or to set an open-circuit voltage specified as the target voltage—with a great deal of time and effort.

Furthermore, it may be necessary to carry out a targeted discharge process to achieve a predetermined target voltage in the battery module and/or a desired depth of discharge (DoD for short)—of the battery module. However, deviations from the predetermined target voltage can also occur. After the discharge process has ended, for example after a discharge current has been switched off, the voltage between the terminals of the battery module increases until the open-circuit voltage is reached. This voltage change after the discharge is completed also causes a deviation from the predetermined target voltage. The open-circuit voltage in the battery module is then usually above the desired target voltage.

For example, document WO 2020/227821 A1 discloses an adapted charging method for a battery in order to accelerate the charging of a battery. For this purpose, at least one discharge pulse is applied to the battery during a charging process of a battery, and a first value of a relaxation voltage is measured during a relaxation process following the discharge pulse, and a second value of a relaxation voltage is measured after a predetermined waiting time. Based on the difference between the two measured voltage values, charging parameters for the charging process are then adjusted. This can be used to accelerate the charging process of the battery using the method described in WO 2020/227821 A1. However, it is hardly possible with this method to specify a desired target voltage for the battery which should be achieved as an open-circuit voltage after charging.

From the document US 2018/0145527 A1, a charging method for a battery is also known to accelerate the charging of a battery, in which battery aging is additionally considered by adjusting a switch-off criterion for ending a charging process of the battery after each charging process or after a predetermined number of charging processes.

### REPRESENTATION OF THE INVENTION

The invention is therefore based on the object of specifying a method and an associated system which make it possible to set a predetermined target voltage on a battery module in a time-efficient manner and with relatively high accuracy.

This object is achieved by a method and by a system according to the independent claims. Advantageous embodiments of the present invention are described in the dependent claims.

According to the invention, the object is achieved by a method of the type mentioned at the outset, in which a battery module is charged or discharged with a charging current until a first switch-off voltage is reached by a voltage dropping between a positive and a negative terminal of the battery module. After the first switch-off voltage is reached, the charging current is switched off and a relaxation curve between the positive and negative terminals of the battery module is measured during a specified period-of-time. A model of the battery module is derived from the measured relaxation curve and the entire relaxation curve is determined using this model. From the relaxation curve determined, a second switch-off voltage is determined in such a way that after the charging current is switched off at the second switch-off voltage, the predetermined target voltage is assumed as the open-circuit voltage of the battery module. The battery module is then further charged or discharged with the charging current until the voltage dropping between the positive and negative terminals of the battery module reaches the second switch-off voltage. Preferably, the battery module is charged or discharged with a constant charging current.

The main aspect of the solution proposed according to the invention is that the battery module can be charged or discharged with a certain predetermined, preferably constant, charging current. This significantly accelerates the charging or discharging of the battery module to a desired charge or discharge state. Furthermore, the predetermined target voltage can be set in the battery module with relatively high accuracy after completion of the charging or discharging process by using the method according to the invention—in particular, by using the model of the battery module determined from a measured portion of the relaxation curve, the entire relaxation curve determined by using the model and based on the second switch-off voltage derived therefrom. After the charging current is switched off, when the second switch-off voltage is reached, the battery module relaxes and the predetermined target voltage is set relatively precisely as the open-circuit voltage in the battery module.

For a charging process, the first switch-off voltage is expediently predetermined in such a way that an open-circuit voltage, which is established after the relaxation curve for the first switch-off voltage at the battery module, is lower than the predetermined target voltage. Analogously, the first switch-off voltage for a discharge process can be predetermined in such a way that an open-circuit voltage, which is established after the relaxation curve for the first switch-off voltage in the battery module, is greater than the predetermined target voltage. It is important that the first switch-off voltage for the battery module to be charged or discharged is selected such that the first switch-off voltage is close to the predetermined target voltage so that a relaxation curve is subsequently measured between the positive and negative terminals of the battery module which corresponds to the target voltage as the open-circuit voltage and approximately to the relaxation curve. For example, the first switch-off voltage can be selected so that it lies within a specifiable range above and/or below the predetermined target voltage or, for example, deviates from the target voltage by a predefined percentage value. The specifiable range or the predefined percentage value can be determined based on empirical values, for example. Furthermore, the first switch-off voltage can be adjusted during use of the method based on measured data (e.g., terminal voltage during the method, measured relaxation curves, etc.) for different battery module types and predetermined target voltages to charge or discharge the battery module being conditioned even more precisely to the desired charge or discharge state.

Furthermore, it is advantageous, if an electrical equivalent circuit diagram of the battery module is used for the model of the battery module, which is parameterized by an adaptive calculation method based on the measured relaxation curve. This makes it easy to approximate and simulate the properties and behavior of the battery module as accurately as possible and thus to set the predetermined target voltage in the battery module as accurately as possible.

It is advantageous, if a least-square method is used as an adaptive calculation method for parameterizing the electrical equivalent circuit diagram of the battery module. With this method, real data—such as the measured portion of the relaxation curve—can be investigated. Assuming that the measured data are close to the underlying “correct” data and that there is a certain relationship between the measured data, this method can be used to find a function that describes this relationship as well as possible. This means an equivalent circuit diagram or a function that describes the properties of the battery module as accurately as possible.

An expedient embodiment of the invention provides that, for parameterization of the electrical equivalent circuit diagram of the battery module, upper limit values and lower limit values are predefined for each of the parameters of the equivalent circuit diagram of the battery module. Predefining limit values is a simple way to prevent the parameters of the equivalent circuit diagram from assuming unrealistic values. This prevents, for example, voltages and/or time constants from assuming values less than zero.

In a further aspect, the invention also relates to a system for conditioning a battery module to a predetermined target voltage, which system has at least one conditioning unit and one analysis unit, wherein the system can be used to charge or discharge a battery module to a predetermined target voltage efficiently and in a time-saving manner.

The conditioning unit can be connected to the positive and negative terminals of the battery module via connecting cables. Furthermore, the conditioning unit is designed to measure a voltage drop between the positive and negative terminals of the battery module and to compare this voltage with a first switch-off voltage and with a second switch-off voltage, to switch off a charging current, when the first and second switch-off voltages are reached, and to measure a relaxation curve between the positive and negative terminals of the battery module for a predetermined period-of-time.

The analysis unit is designed to derive a model of the battery module from the relaxation curve measured by the conditioning unit for the predetermined period-of-time, with which the entire relaxation curve can be determined, and to determine a second switch-off voltage from the entire relaxation curve. The analysis unit can be designed as a stand-alone unit and have a communication connection with the conditioning unit. This would make it very easy to use the analysis unit with different conditioning units or to exchange it very easily.

Alternatively, the analysis unit can also be integrated into the conditioning unit. Thus, the conditioning unit and the analysis unit would form a single unit, which would be easy to handle or transport.

Ideally, upper and lower limit values, which are used for the parameterization of the model of the battery module in the course of the method according to the invention, can be stored in the analysis unit. For this purpose, the analysis unit can have a storage unit or a storage area, for example. It would also be advantageous, that the limit values for the parameterization are entered, for example, via an input/output unit and then stored in the analysis unit. Furthermore, measurement data (e.g., voltage curves, relaxation curves, etc.) for different battery module types and target voltages can be stored in the storage unit or in the storage area, which can then be used for analysis purposes and/or to adapt the first switch-off voltage. Alternatively, this data could be stored directly in the conditioning unit.

An expedient embodiment of the invention provides that the conditioning unit has a temperature sensor with which a current battery temperature can be determined. This means that, for example, temperature-dependent behavior of the battery module—e.g., different relaxation curves at different temperatures, etc. —can be considered for conditioning the battery module.

### BRIEF DESCRIPTION OF THE FIGURES

The present invention is described in greater detail below with reference to FIG. 1 to 4 which show exemplary, schematic, and non-limiting advantageous embodiments of the invention. In the figures:

FIG. 1 shows a sequence of the method according to the invention for conditioning a battery module

FIG. 2 shows a simplified electrical equivalent circuit diagram of the battery module

FIG. 3 shows a curve of current and voltage during a charging process of the battery module according to the method according to the invention

FIG. 4 shows a system for carrying out the method according to the invention for conditioning a battery module.

### EXECUTION OF THE INVENTION

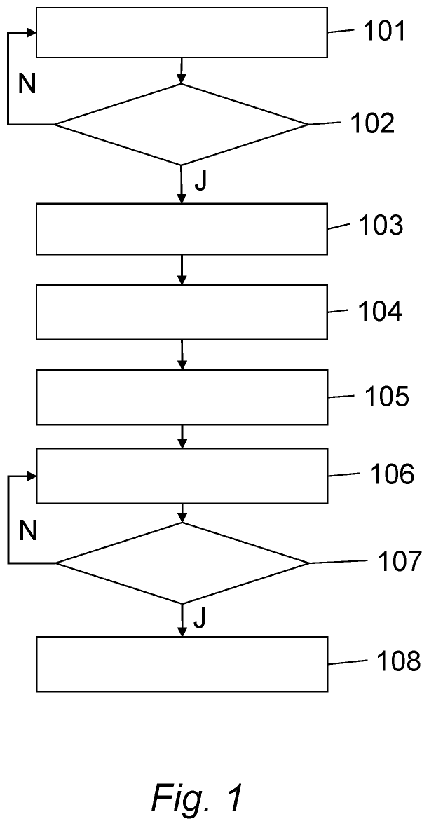

FIG. 1 is an example of a sequence of the method for conditioning a battery module BM. For this purpose, for example, terminals Kp, Kn of the battery module BM—i.e., a positive terminal Kp and a negative terminal Kn of the battery module BM—are connected via connecting cables L to a conditioning unit MB or a charging device MB. The conditioning unit MB or the charging device MB provides a charging current I_{L} which then can charge the battery module BM to a predetermined target voltage Uz and thus to a desired state of charge, or discharged to a desired depth of discharge.

To start the method, a charging current I_{L} is switched on for a first charging step 101. The charging current I_{L} is predefined, for example in terms of magnitude or as a time profile of a current, and can be a constant charging current I_{L}, for example. For example, a maximum permissible charging current I_{L} is selected for the given battery module BM. It can be specified by the manufacturer and/or for a battery type used, which can accelerate charging or discharging. During the first charging step 101, the battery module BM is charged with the charging current I_{L} during a charging process or discharged during a discharging process. Furthermore, during the first charging step 101 and the further method, a voltage Ut drop between the positive and the negative terminal Kp, Kn of the battery module BM is continuously measured.

In a first verification step 102, it is checked whether the measured voltage Ut reaches a first switch-off voltage Ua1. If it is determined in the first verification step 102 that the voltage Ut measured between the positive and negative terminals Kn, Kp of the battery module BM has reached the first switch-off voltage Ua1, the charging current I_{L} is switched off. This triggers a relaxation process in the battery module BM. In a measuring step 103, a profile of the relaxation process or a relaxation curve is measured for a predetermined period-of-time, e.g., by the conditioning unit MB or by the charging device MB. For this purpose, for example, a curve of the voltage Ut drop between the positive and negative terminals Kp, Kn of the battery module BM is recorded during the predetermined period-of-time. As a result of the measuring step 103, a portion of the relaxation curve of the battery module BM is obtained.

The first switch-off voltage Ua1, at which the charging current I_{L} is switched off, is selected for a charging process in such a way that, for example, after an entire relaxation process, an open-circuit voltage would be established at the battery module BM which is less than the predetermined target voltage. Analogously, for example, for a discharge process, a first switch-off voltage Ua1 is selected such that after an entire relaxation process in the battery module BM, an open-circuit voltage would be established which is greater than the target voltage. The selection of the first switch-off voltage Ua1 can, for example, be based on empirical values for the battery module BM to be conditioned. For example, a voltage value can be selected for the first switch-off voltage Ua1 which lies within a specifiable range above and/or below the predetermined target voltage Uz or which deviates from the predetermined target voltage Uz by a specifiable percentage. When selecting the first switch-off voltage Ua1, it is important that it is close to the predetermined target voltage Uz so that the battery module has approximately the same relaxation behavior.

The first switch-off voltage Ua1 can also be adapted for different battery module types and predetermined target voltages Uz or charge or discharge states over time. For example, for an initial charging or discharging process of a battery module type to a predetermined target voltage Uz, the first switch-off voltage Ua1—as listed above—can be specified. Each time the conditioning procedure is carried out for the respective battery module type, data (e.g., voltage curve between the terminals Kp, Kn, relaxation curve, etc.) can be collected and subsequently evaluated. The first switch-off voltage Ua1 can then be adjusted based on these measured data to set the specified target voltage Uz in the battery module BM even more precisely.

The period-of-time, during which the relaxation curve or the curve of the voltage Ut between the positive and negative terminals Kp, Kn of the battery module BM is measured in measuring step 103, can be specified as, for example, a few minutes—i.e., ideally two minutes. Since the greatest changes in the relaxation curve (e.g., transient voltage drop during charging, transient voltage increase during discharging, etc.) usually occur immediately after the charging current I_{L} is switched off, the specified period-of-time is selected such that these changes are captured in the measured relaxation curve.

From the measured relaxation curve, a model for the battery module BM can be derived in a modeling step 104, which model represents a good approximation of the behavior of the battery module BM. As a starting point for the model of the battery module BM, for example, an electrical equivalent circuit diagram is used, through which the properties and behavior of the battery module BM can be approximated as accurately as possible.

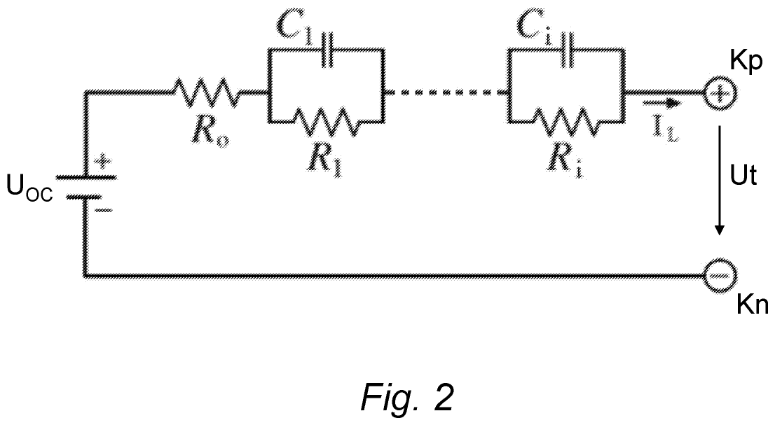

FIG. 2 shows, for example, such a simplified electrical equivalent circuit diagram, which is used, for example, in the modeling step 104 to derive the model of the battery module BM.

This equivalent circuit diagram shows, for example, an ideal voltage source Uoc, which describes an open-circuit voltage Uoc of the battery module BM. The open-circuit voltage Uoc depends on the current charge level of the battery module BM, and is higher the more the battery module BM is charged. A resistance Ro is arranged in series with the voltage source Uoc, describing an internal resistance Ro of the battery module. The resistance Ro also depends on the current charge state of the battery module BM. A value for the internal resistance Ro can be determined, for example, from the measurement of the relaxation curve in measuring step 103—e.g., from a voltage jump at the beginning of the measurement. Alternatively, the value of the internal resistance Ro can also be taken from data sheets of the given battery module BM. A current I_{L} describes the charging current I_{L} of the battery module BM. Depending on the sign of the current I_{L}, the battery module BM is either charged or discharged. A time-dependent voltage Ut drops between a positive terminal Kp and a negative terminal Kn of the equivalent circuit diagram. This voltage Ut corresponds to the open-circuit voltage Uoc when the battery module is completely relaxed—i.e., in a steady state and no load is connected between the terminals Kp, Kn.

Furthermore, several RC elements R1C1, . . . , RiCi are arranged in series between the internal resistance Ro and the positive terminal Kp of the battery module BM. The RC elements R1C1, . . . , RiCi each have a parallel connection of a resistor R1, . . . , Ri and a capacitor C1, . . . , Ci. The respective capacitors C1, . . . , Ci represent a capacitive behavior inside the battery module BM. The resistors R1, . . . , Ri arise from charge transport inside the battery module BM. The RC elements R1C1, . . . , RiCi are used in the equivalent circuit diagram to model a dynamic or time-dependent behavior of the battery module BM, such as a relaxation behavior of the battery module BM, with corresponding time constants. For a good approximation of the relaxation behavior, at least two RC elements R1C1, R2C2 are provided in the equivalent circuit diagram. In order to achieve a good level of accuracy with the lowest possible computational effort, the equivalent circuit diagram contains, for example, three RC elements R1C1, . . . , R3C3.

In the modeling step 104, for example, a model of the battery module BM is determined on the basis of a simplified electrical equivalent circuit diagram—as shown in FIG. 2. For this purpose, the equivalent circuit diagram of the battery module BM is parameterized using the relaxation curve measured in measuring step 103. This means that suitable parameter values for the open-circuit voltage Uoc, the internal resistance Ro and for the RC elements R1C1, . . . , RiCi used for the equivalent circuit diagram are derived from the measured portion of the relaxation curve.

For example, a so-called least squares method is used to calculate the appropriate parameter values. The least square method derives its optimality criterion directly from the known data, such as the portion of the relaxation curve measured in measuring step 103. This criterion describes a deterministic error function, which consists of the sum of the squared deviations of the given function, which is why it is also called the “method of least squares.” The calculation of suitable parameter values from the measured portion of the relaxation curve using the least square method can be carried out, for example, using calculation software such as GNU Octave. GNU Octave is free software for numerical solutions of mathematical problems (e.g., matrix calculations, (differential) systems of equations, integration, etc.).

To be able to determine the parameter values for the electrical equivalent circuit diagram of the battery module BM and thus the model of the battery module BM from the measured portion of the relaxation curve, the relaxation curve after a charging process for the electrical equivalent circuit diagram with, for example, three RC elements R1C1, . . . , R3C3 is described with the following formula:

$$Ut = Uoc + IL 0 * R 1 * {e}^{- \frac{1}{R 1 * C 1} * t} + IL 0 * R 2 * {e}^{- \frac{1}{R 2 * C 2} * t} + IL 0 * R 3 * {e}^{- \frac{1}{R 3 * C 3} * t}$$

Where:
Ut is a time-dependent voltage between the terminals Kp, Kn of the battery module BM;
Uoc or Uo is the no-load voltage or open-circuit voltage to which the relaxation curve drops after a long time;
I_{L0} is the charging current I_{L} with which the battery module BM was charged until the first switch-off voltage Ua1 was reached;
R1, R2, R3 are resistance values of the RC elements in the equivalent circuit diagram;
C1, C2, C3 are capacitance values of the RC elements in the equivalent circuit diagram;
t is a time variable; and
e is Euler's number.

This formula can be simplified by combining the different resistance values R1, R2, R3 and capacitance values C1, C2, C3 into time constants τ1, τ2, τ3. The time constants τ1, τ2, τ3 can be used to estimate the time duration required by each of the RC elements R1C1, . . . , R3C3 to discharge the voltage I_{L0}*R1, I_{L0}*R2, I_{L0}*R3 which drops over the given RC element R1C1, . . . , R3C3. The products of the current I_{L0} and the respective resistance values R1, R2, R3 can be combined to form voltage drops U1, U2, U3 at the given RC elements R1C1, . . . , R3C3. This results in a simplified formula for the time-dependent voltage Ut between the terminals Kp, Kn, which describes the relaxation curve of the battery module BM after a charging process:

$$Ut = Uo + U 1 * {e}^{- \frac{t}{τ 1}} + U 2 * {e}^{- \frac{t}{τ 2}} + U 3 * {e}^{- \frac{t}{τ 3}}$$

Parameter values for the voltages Uo, U1, U2, U3, as well as for the time constants τ1, τ2, τ3 can be determined using this simplified formula and the portion of the relaxation curve measured in measuring step 103. So that these parameter values do not assume unrealistic values (for example, negative values, etc.), upper and lower limit values are set for the individual parameter values of the voltages Uo, U1, U2, U3 and time constants τ1, τ2, τ3.

By specifying upper and lower limits, additional roles for the individual parameters can be defined. For example, the parameter value of the voltage Uo indicates a voltage value to which the voltage Ut drops after a long time. This voltage value Uo corresponds to the open-circuit voltage of the battery module BM. An upper limit value and a lower limit value of the voltage Uo are determined, for example, as a percentage of a first measured value of the voltage Ut, after a transient voltage drop after the charging current I_{L} is switched off. This means that, for the limit values of the voltage Uo, the first measured value of the relaxation curve measured in measuring step 103 after the transient voltage drop is used.

The voltage parameter values U1, U2, U3 and the corresponding time constants τ1, τ2, τ3 largely determine the given exponential voltage drops. For example, the first voltage U1 and a first time constant T1 describe a first, rapid region of the voltage drop, a second voltage U2 and second time constant 12 describe a second, middle region of the voltage drop, and third voltage U3 and a third time constant 13 describe a third, slow region of the voltage drop in the relaxation curve after the charging process of the battery module Bm. The lower limit value for the parameter values of the voltages U1, U2, U3 is, for example, zero in order to avoid negative voltage values. For example, a value of 1 volt can be selected as the upper limit value of the voltage parameters U1, U2, U3. Depending on the battery module BM to be conditioned and its properties, other voltage values can also be used for the upper limit value of the respective voltage parameters U1, U2, U3. The upper and lower limit values of the time constants τ1, τ2, τ3 can be predefined, for example, such that each of the respective ranges of the voltage drop (i.e., rapid, middle, or slow) are taken into account accordingly.

Analogously to the modeling of the relaxation curve of the battery module BM after a charging process, a relaxation curve for the battery module after a discharging process can also be modeled in the modeling step 104. For this purpose, a portion of the relaxation curve measured in measuring step 103 for the predetermined period-of-time (e.g., 2 minutes)—this time after the charging current I_{L} is switched off during the discharging process—as well as the simplified electrical equivalent circuit diagram of the battery module BM described above, are also used. The corresponding parameter values are then determined again using the least squares method. For example, the following formula can be used for the time-dependent voltage Ut at the terminals Kp, Kn of the battery module BM:

$$Ut = Uo + U 1 * ( 1 - {e}^{- \frac{t}{τ 1}} ) + U 2 * ( 1 - {e}^{- \frac{t}{τ 2}} ) + U 3 * ( 1 - {e}^{- \frac{t}{τ 3}} )$$

The voltage Uo indicates a voltage value which largely corresponds to the open-circuit voltage of the battery module BM or to which the time-dependent voltage Ut rises after a long time. The voltage parameters U1, U2, U3 and the time constants τ1, τ2, τ3 in this case each determine exponential voltage increases, and a distinction is made between a rapid, middle, and slow region of the voltage increase. Upper and lower limit values for the parameter values of the voltages U1, U2, U3 and the time constants τ1, τ2, τ3 can likewise be specified—adapted accordingly—for the determination of the model of the battery module BM during the discharge process.

After the parameter values for the voltages Uo, U1, U2, U3 and time constants τ1, τ2, τ3 have been determined in the modeling step 104, for example by means of the least square method from the portion of the relaxation curve measured in the measuring step 103, the entire relaxation curve for the given charging process or for the given discharging process of the battery module BM can be determined in a simulation step 105. This means that the curve of the time-dependent voltage Ut, from when the charging current I_{L} is switched off until the open-circuit voltage Uo is reached between the terminals Kp, Kn of the battery module BM is simulated. From this determined, overall relaxation curve, a total difference can be determined between the voltage when the charging current I_{L} is switched off at the terminals Kp, Kn of the battery module BM—i.e., the first switch-off voltage Ua1—and an open-circuit voltage Uo that occurs in the battery module BM after a long period-of-time (e.g., at least one hour up to several hours). From this, a second switch-off voltage Ua2 can then be determined in simulation step 105, such that, after the charging current I_{L} is switched off at the second switch-off voltage Ua2, the predetermined target voltage Uz is adopted as the open-circuit voltage of the battery module.

In a second charging step 106, the battery module BM is further charged or discharged with the charging current I_{L}, which corresponds, for example, to the maximum permissible charging current I_{L} for the battery module BM. In a second verification step 107, it is checked whether the voltage Ut, which drops between the positive and the negative terminal Kp, Kn of the battery module BM and is continuously measured, reaches the second switch-off voltage Ua2 determined in the simulation step 105.

If it is determined in the second verification step 107 that the second switch-off voltage Ua2 has been reached by the voltage Ut drop between the positive and the negative terminal Kp, Kn, the charging current I_{L} is switched off again—or permanently—in a switch-off step 108. After the charging current I_{L} is switched off, a relaxation process starts again in the battery module BM. In the switch-off step 108, after the charging process, the voltage Ut at the battery module BM drops to an open-circuit voltage which corresponds to the predetermined target voltage Uz. After a discharge process, the voltage Ut of the battery module BM rises to an open-circuit voltage which corresponds to the predetermined target voltage Uz after the charging current I_{L} is switched off in the switch-off step 108.

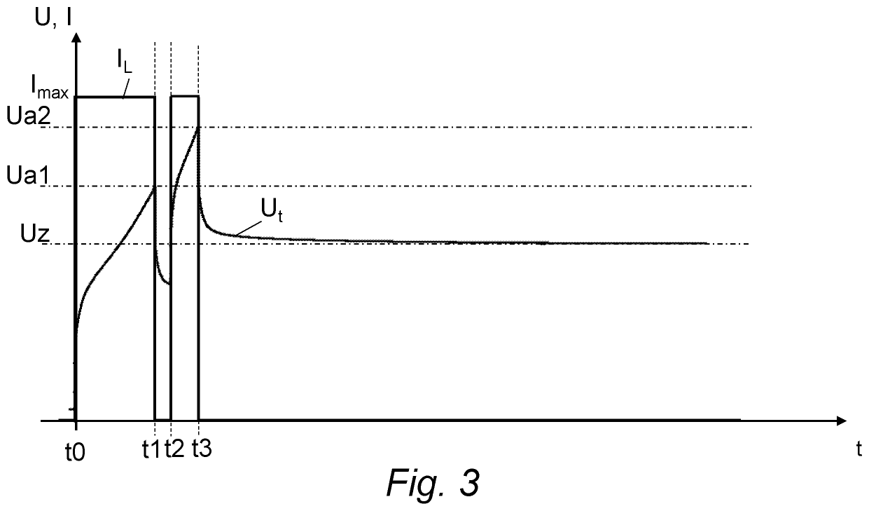

FIG. 3 shows, as an example, a time curve of the voltage Ut between the positive terminal Kp and the negative terminal Kn of the battery module, as well as a time curve of the, —in this case, constant—charging current I_{L} during a charging process of the battery module BM. The conditioning method according to the invention is used to charge the battery module BM to a desired charge state or to set the predetermined target voltage Uz. The time t is plotted on a horizontal axis. Voltage U and current I are plotted on a vertical axis. Furthermore, the predetermined target voltage Uz, which is to be set as the open-circuit voltage in the battery module BM after completion of the charging process example, as well as the first switch-off voltage Ua1 and the second switch-off voltage Ua2, are plotted on the vertical axis. The vertical axis also shows a maximum charging current value Iₘₐₓ permissible for the battery module BM.

For example, at a start time t0, the charging process of the battery module BM begins. For this purpose, the charging current I_{L} is switched on at the starting time t0 to charge the battery module BM, for example, with the maximum permissible value Iₘₐₓ for the charging current I_{L}. As a result, the time-dependent voltage Ut between the positive and negative terminals Kp, Kn of the battery module BM begins to rise. If the time-dependent voltage Ut reaches the first switch-off voltage Ua1 at a first point in time t1, the charging current I_{L} is switched off. The period-of-time from the start time t0 to the first time t1 corresponds to the first charging step 101. The switch-off voltage Ua1, in order to terminate the first charging step 101 at the first time t1, is selected such that, after an entire relaxation process, an open-circuit voltage is set for the first switch-off voltage Ua1 which is below the target voltage Uz. For the selection of the first switch-off voltage Ua1, it is also important that it is close to the predetermined target voltage Uz so that the battery module BM has approximately the same relaxation behavior as at the target voltage Uz. In FIG. 3, for example, a voltage value was selected for the first switch-off voltage Ua1 which is a few millivolts above the target voltage Uz, for example within a specifiable range. It would also be conceivable to select a voltage value for the first switch-off voltage Ua1 which is a few millivolts below the target voltage Uz, for example within a specifiable range.

By switching off the charging current I_{L} at the first time t1, a relaxation process is generated in the battery module BM and the voltage Ut begins to decrease due to the relaxation process. The relaxation curve and/or the curve of the voltage Ut is measured in measuring step 103 for a predetermined period-of-time (e.g., two minutes). The measuring step 103 is started, for example, at the first time t1 and terminated at a second time t2 after the expiration of the predetermined period-of-time. From the portion of the relaxation curve measured between the first time t1 and the second time t2, the model of the battery module BM is then determined in the modeling step 104, with which the entire relaxation curve of the battery module for a desired state of charge as well as the second switch-off voltage Ua2 can be determined in the simulation step 105.

At the second time t2, the charging current I_{L} is switched on again in order to continue charging the battery module with the maximum permissible value Iₘₐₓ of the charging current I_{L}. This means that at the second time t2, the second charging step 106 begins. The battery module BM continues to be charged until the voltage Ut reaches the second switch-off voltage Ua2 at a third time t3. At the third time t3, the charging current I_{L} is finally switched off. From the third point in time t3 or after the charging current I_{L} is switched off, the voltage Ut decreases—according to the relaxation curve—towards the open-circuit voltage, which corresponds to the predetermined target voltage Uz. The charging process can be carried out in a time-efficient manner with the maximum permissible charging current Iₘₐₓ, as shown in FIG. 3, wherein the voltage Ut drops to the predetermined target voltage Uz with relatively high accuracy after completion of the charging process. However, during the charging process it must be ensured that the second switch-off voltage Ua2 is within a permissible voltage range for the battery module BM, since the battery module is overcharged up to this voltage value Ua2.

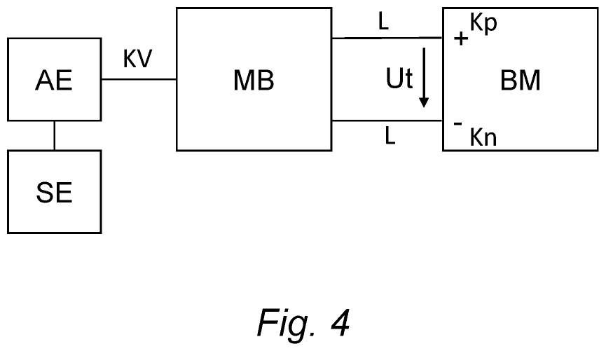

FIG. 4 shows a schematic example of a system which is configured to carry out the conditioning method shown by way of example in FIG. 1 for a battery module BM, in particular a battery module BM for a traction or drive battery. The battery module BM can be connected to a conditioning unit MB or a charging device MB via connecting cables L for a conditioning process—i.e., for charging or discharging to a desired state of charge or to a desired depth of discharge. For this purpose, for example, a positive terminal Kp and a negative terminal Kn of the battery module BM are each connected to the conditioning unit MB via a connecting cable L to set the predetermined target voltage Uz in the battery module BM by appropriately charging or discharging the battery module BM. The target voltage Uz, as an open-circuit voltage between the positive terminal Kp and the negative terminal Kn in the steady state of the battery module BM, should drop after completion of the corresponding charging or discharging process.

To carry out the method, the conditioning unit MB is designed—in addition to charging or discharging the battery module BM with the charging current I_{L}— to measure the voltage Ut which changes over time due to the respective charging or discharging process, wherein the voltage Ut drops between the positive terminal Kp and the negative terminal Kn of the battery module BM. Furthermore, the conditioning unit MB compares the measured voltage Ut, e.g., in the first verification step 102, with the first switch-off voltage Ua1 and in the second verification step 107 with the second switch-off voltage Ua2 in order to switch off the charging current I_{L} when the first or second switch-off voltage Ua1, Ua2 is reached. Furthermore, the conditioning unit MB is designed to measure a relaxation curve—i.e., the curve of the voltage Ut between the positive and negative terminals Kp, Kn of the battery module BM—for a predetermined period-of-time after the charging current I_{L} has been switched off when the first switch-off voltage Ua1 is reached.

Furthermore, the conditioning unit MB can have a temperature sensor (e.g., an infrared temperature sensor). The temperature sensor can be used, for example, to determine and monitor the current battery temperature. The determined temperature of the battery module BM can then, for example, be incorporated into the conditioning process to achieve the predetermined target voltage Uz even more precisely.

Furthermore, the system has an analysis unit AE, which can be designed as an independent unit and is connected to the conditioning unit MB via a communication connection KV. Alternatively, the analysis unit AE can also be integrated into the conditioning unit MB. The analysis unit AE is designed to derive a model of the battery module BM from a portion of the relaxation curve measured by the conditioning unit MB for the specified period-of-time. For this purpose, the analysis unit AE can, for example, use a simplified, electrical equivalent circuit diagram of the battery module BM, which is shown in FIG. 2, and determine parameter values for this using an adaptive calculation method, such as the least squares method. For the parameterization of the equivalent circuit diagram, upper and lower limit values for the respective parameters can be stored in the analysis unit AE, for example in a storage unit SE, which are adapted, for example, to common, desired charge states (e.g., SoC 60%) or discharge depths (e.g., DoD 30%) of the battery module BM. The storage unit SE can, for example, be integrated into the analysis unit AE or be designed as an external storage unit SE which is connected to the analysis unit AE.

Furthermore, the analysis unit AE is designed to determine or simulate the entire relaxation curve—i.e., the entire curve of the voltage Ut between the positive and the negative terminal Kp, Kn from the first switching off of the charging current I_{L} at the first switch-off voltage Ua1 until the open-circuit voltage is reached at the battery module BM—using the derived model of the battery module BM. From the determined or simulated entire relaxation curve, the analysis unit AE then determines the second switch-off voltage Ua2 and can forward this, for example, to the conditioning unit MB, which can then continue the conditioning process up to the second switch-off voltage Ua2.

1. A method for conditioning a battery module, in particular a battery module of a traction battery, to a predetermined target voltage, wherein:
the battery module is charged or discharged with a charging current until a first switch-off voltage is reached by a voltage dropping between a positive and a negative terminal of the battery module,
the charging current is switched off and a relaxation curve between the positive and negative terminal of the battery module is measured for a predetermined period-of-time,
a model of the battery module is derived from the measured relaxation curve,
the entire relaxation curve is determined using the model of the battery module and a second switch-off voltage is determined from the entire relaxation curve in such a way that, after the charging current has been switched off, when the second switch-off voltage has been reached, the predetermined target voltage is assumed as the open-circuit voltage of the battery module, and
the battery module continues to be charged or discharged with the charging current until the second switch-off voltage is reached by the voltage dropping between the positive and negative terminal of the battery module.

2. The method according to claim 1, wherein the battery module is charged or discharged with a constant charging current.

3. The method according to claim 1, wherein, for a charging process, the first switch-off voltage is predetermined in such a way that an open-circuit voltage, which is established for the first switch-off voltage after the relaxation curve, is less than the predetermined target voltage.

4. The method according to claim 1, wherein, for a discharge process, the first switch-off voltage is predetermined in such a way that an open-circuit voltage, which is established for the first switch-off voltage after the relaxation curve, is greater than the predetermined target voltage.

5. The method according to claim 1, wherein an electrical equivalent circuit diagram of the battery module is used for the model of the battery module, which is parameterized by an adaptive calculation method based on the measured relaxation curve.

6. The method according to claim 5, wherein a least square method is used as the adaptive calculation method.

7. The method according to claim 5, wherein that for a parameterization of the electrical equivalent circuit diagram of the battery module, upper limit values and lower limit values for respective parameters of the electrical equivalent circuit diagram of the battery module are predetermined.

8. A system for conditioning a battery module, in particular a battery module of a traction battery, to a predetermined target voltage, wherein at least the following are provided:
a conditioning unit which can be connected to a positive terminal and a negative terminal of the battery module via connecting cables, and which is at least designed to measure a voltage dropping between the positive and negative terminals of the battery module and to compare the voltage to a first switch-off voltage and a second switch-off voltage, to switch off a charging current, when the first and second switch-off voltages are reached, and to measure a relaxation curve between the positive and negative terminals of the battery module for a predetermined period-of-time; and
an analysis unit which is at least designed to derive a model of the battery module from the relaxation curve measured by the conditioning unit for the predetermined period-of-time, with which model the entire relaxation curve can be determined, and to determine a second switch-off voltage from the entire relaxation curve.

9. The system according to claim 8, wherein the analysis unit is designed as an independent unit, wherein the analysis unit has a communication connection with the conditioning unit.

10. The system according to claim 8, wherein the analysis unit is integrated into the conditioning unit.

11. The system according to claim 8, wherein upper limit values and lower limit values for parameterizing the model of the battery module are stored in the analysis unit.

12. The system according to claim 8, wherein that the conditioning unit has a temperature sensor for determining a current battery temperature.
